(19) United States
(12) Patent Application Publication
(10) Pub. No.: US 2026/0090343 A1
(43) Pub. Date: Mar. 26, 2026

(54) LINE EDGE ROUGHNESS REDUCTION THROUGH APPLICATION OF TENSILE STRESS

(71) Applicant: Applied Materials Inc., Santa Clara, CA (US)

(72) Inventors: SIVANANDHA KANAKASABAPATHY, Pleasanton, CA (US); ZHIYU HUANG, Sunnyvale, CA (US); RUDY WOJTECKI, East Garrison, CA (US); CHARITH NANAYAKKARA, Rowley, MA (US); JOHN HAUTALA, Beverly, MA (US)

(21) Appl. No.: 19/309,403

(22) Filed: Aug. 25, 2025

Related U.S. Application Data
(60) Provisional application No. 63/697,355, filed on Sep. 20, 2024.

(51) Int. Cl. H01L 21/027

(52) U.S. Cl. CPC H10P 76/2041; H10P 76/2043

(57) ABSTRACT

Embodiments described herein relate to a method, that obtaining a substrate with a patterned resist layer positioned over a patterning stack, wherein the patterned resist layer comprises a first low frequency roughness. In an embodiment, the method further includes forming a capping layer on the patterned resist layer. In an embodiment, a bottom of the patterned resist layer is exposed, and the patterned resist layer has a second low frequency line edge roughness that is lower than the first low frequency line edge roughness after the capping layer is formed.

### CROSS-REFERENCE TO RELATED APPLICATIONS

This application claims the benefit of U.S. Provisional Application No. 63/697,355, filed on Sep. 20, 2024, the entire contents of which are hereby incorporated by reference herein.

### BACKGROUND

### 1) Field

Embodiments relate to the field of semiconductor manufacturing and, in particular, extreme ultraviolet (EUV) patterning of a resist layer with reduced low frequency line edge roughness that is enabled by the application of a capping layer to the patterned resist layer.

### 2) Description of Related Art

Extreme ultraviolet (EUV) photoresists allow for the continued scaling to smaller features that are patterned on a semiconductor substrate. One limiting factor to the increased scaling is the presence of high line edge roughness (LER). LER can generally be characterized into two components: high frequency LER and low frequency LER. High frequency LER generally includes roughness measurements of the sidewalls of the patterned photoresist on the scale of approximately one-half of the pitch or less. Low frequency LER generally includes roughness measurements of the sidewalls of the patterned photoresist on the scale of approximately two times the pitch or more.

In order to improve pattern transfer, both high frequency LER and low frequency LER should be addressed. High frequency LER can be reduced through certain etching processes. However, issues related to low frequency LER cannot be addressed through etching processes.

### SUMMARY

Embodiments described herein relate to a method, that includes obtaining a substrate with a patterned resist layer positioned over a patterning stack, wherein the patterned resist layer comprises a first low frequency roughness. In an embodiment, the method further includes forming a capping layer on the patterned resist layer. In an embodiment, a bottom of the patterned resist layer is exposed, and the patterned resist layer has a second low frequency line edge roughness that is lower than the first low frequency line edge roughness after the capping layer is formed.

Embodiments described herein relate to a method that includes obtaining a substrate with a patterned resist layer positioned over a patterning stack, where the patterned resist layer includes a line, and the lines has a curvature with a first magnitude. In an embodiment, the method further comprises forming a capping layer over the line, where the capping layer covers a portion of a sidewall of the line. In an embodiment, the capping layer induces a tensile stress into the line to change the curvature so that the curvature has a second magnitude that is smaller than the first magnitude.

Embodiments described herein relate to a method, that includes obtaining a substrate with a patterned resist layer with a plurality of lines positioned over a patterning stack, where the patterned resist layer includes a chemically amplified resist layer or a metal oxide resist layer. In an embodiment, the method further comprises forming a capping layer over the plurality of lines, where the capping layer covers upper portions of the plurality of lines, and bottom portions of the plurality of lines are exposed. In an embodiment, the method further includes transferring a pattern of the patterned resist layer into the patterning stack.

### BRIEF DESCRIPTION OF THE DRAWINGS

FIG. 1A is a cross-sectional illustration of a device with a patterning stack over a substrate that includes a patterned resist layer, in accordance with an embodiment.

FIG. 1B is a plan view illustration of the device in FIG. 1A that depicts poor low frequency line edge roughness, in accordance with an embodiment.

FIG. 2A is a cross-sectional illustration of a device with a patterning stack that includes a patterned resist layer with a capping layer, in accordance with an embodiment.

FIG. 2B is a plan view illustration of the device in FIG. 2A that depicts improved low frequency line edge roughness after the application of the capping layer onto upper portions of the patterned resist layer, in accordance with an embodiment.

FIGS. 3A-3H are illustrations that depict a process for forming a device with a pattern, where the pattern has improved low frequency line edge roughness due to the use of a capping layer over portions of a patterned resist layer, in accordance with an embodiment.

FIG. 4 is a flow diagram that describes a process for forming a device with a pattern, where the pattern has improved low frequency line edge roughness due to the use of a capping layer over portions of a patterned resist layer, in accordance with an embodiment.

FIG. 5 illustrates a block diagram of an exemplary computer system that may be used in conjunction with a processing tool, in accordance with an embodiment.

### DETAILED DESCRIPTION

Embodiments described herein include extreme ultraviolet (EUV) patterning of a resist layer with reduced low frequency line edge roughness that is enabled by the application of a capping layer to the patterned resist layer. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, both high frequency line edge roughness (LER) and low frequency LER can contribute to poor pattern transfer through a patterning stack below a photoresist material, such as an EUV photoresist material. While etching processes can be used to address poor high frequency LER, it is harder to reduce low frequency LER.

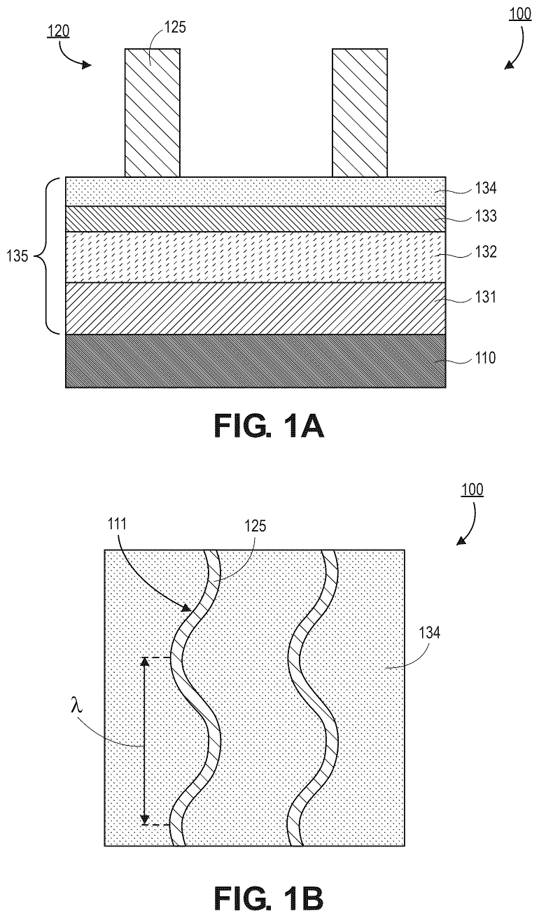

Referring now to FIG. 1A, a cross-sectional illustration of a device 100 that may suffer from poor low frequency LER is shown. The device 100 may comprise a substrate 110 and a patterning stack 135 may be provided over the substrate 110. The patterning stack 135 may include any number of layers in order to implement a desired patterning result. For example, layers 131-134 are shown in FIG. 1A. The layers 131-134 may include materials that function as hardmask layers, antireflective coating layers, underlayers to improve the development process within the overlying photoresist layer 120, or the like.

FIG. 1A illustrates a patterned resist layer 120 that is provided over the patterning stack 135. The patterned resist layer 120 may comprise a plurality of lines 125 that extend into and out of the plane of FIG. 1A. The lines 125 may be formed with any suitable lithographic exposure and development process. For example, an extreme ultraviolet (EUV) exposure process may be used. The patterned resist layer 120 may comprise a chemically amplified resist (CAR) or a metal oxide resist (MOR).

Referring now to FIG. 1B, a plan view illustration of the device 100 is shown. The plan view of the device 100 illustrates the profile of the lines 125. As shown, the lines 125 have poor low frequency LER. That is, the lines 125 may have a long-range undulation as indicated by the curved sidewalls 111 the lines 125. For example, peak-to-peak distances of the curvature (represented by the distance A) may be greater than approximately 5 nm, up to approximately 10 nm or more, up to approximately 50 nm or more, or up to approximately 100 nm or more. The magnitude of each peak may be up to approximately 2 nm or more, or up to approximately 5 nm or more. While the lines 125 are shown as having a relatively consistent curvature (e.g., sinusoidal in FIG. 1B), it is to be appreciated that the curvature may be irregular or exhibit a random “wiggling” profile.

Since the lines 125 are used as the mask in order to transfer the pattern into the underlying patterning stack 135, the poor low frequency LER is also transferred into the underlying patterning stack 135. This can lead to improper pattern development within the substrate 110, which may result in defective devices. While high frequency LER may be correctable through control of the plasma etching process used to transfer the pattern into underlying layers, the low frequency LER persists into the underlying layers.

Accordingly, embodiments disclosed herein include a process for physically altering the patterned lines of the patterned resist layer. The physical change may be implemented through the application of a tensile force on the resist material. In some instances, the resist material is deformable by the application of the tensile stress so that the patterned lines can be straightened. That is, the peak magnitudes may be reduced and/or the peak-to-peak distance may be increased. This results in an overall reduction in the low frequency LER, which improves the LER overall.

In a particular embodiment, the tensile stress may be applied to the patterned lines of the resist layer through the application of a capping layer onto the patterned lines. In an embodiment, the capping layer may be applied with a deposition process that selectively forms the capping layer on an upper portion of the patterned lines. That is, a bottom portion of the patterned lines may remain exposed after the deposition of the capping layer. Selective deposition of the capping layer may be implemented with an angled deposition process, such as an angled physical vapor deposition (PVD) process or an angled chemical vapor deposition (CVD) process. Keeping the capping layer off of a lower portion of the patterned lines may allow the patterned lines to freely displace in response to the induced stress in order to reduce the low frequency LER. In an embodiment, the capping layer may comprise a material that induces the tensile stress into the patterned lines. For example, the capping layer may comprise amorphous silicon, silicon nitride, carbon, silicon oxide, or combinations thereof. More generally, the material for the capping layer has a material composition that is different than a material composition of the patterned lines of the resist layer.

In some embodiments, the tensile stress induced by the capping layer may be augmented through the use of one or more additional treatments that are applied to the device. The treatments may include one or more of an ultraviolet (UV) treatment, an annealing treatment, and/or an oxidation treatment. Such treatments may be applied to the device before and/or after the deposition of the capping layer. In some instances, the treatments may modify the atomic arrangement of the patterned lines and/or the capping layer in order to generate tensile stress in the material through changes in the lattice structure.

In some embodiments, the capping layer may reduce the spacing between neighboring patterned lines. If the intrusion into the space between patterning lines results in issues with subsequent pattern transfer, embodiments may also comprise a trimming operation. For example, a directional etching process may be used in order to selectively remove portions of the capping layer that are deposited over the sidewalls of the patterned lines. In such an embodiment, the capping layer may persist along only top surfaces of the patterned lines. Despite the removal of some portions of the capping layer, the tensile stress generation in the patterned lines provided by the residual portion of the capping layer may be sufficient to significantly reduce the low frequency LER.

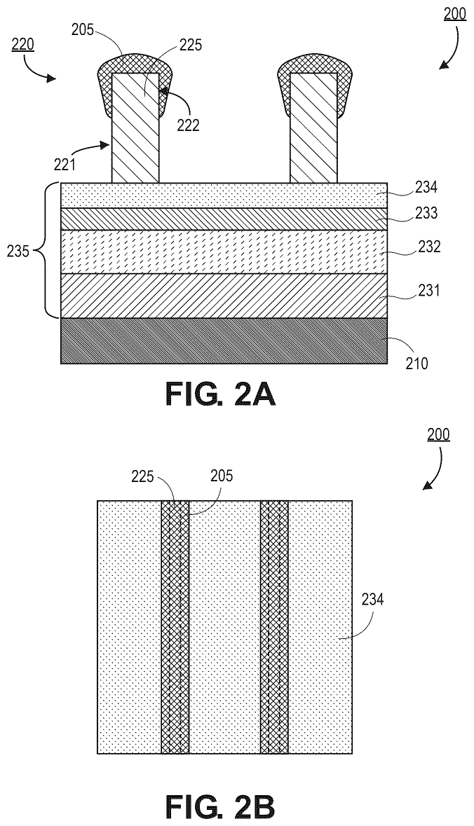

Referring now to FIG. 2A, a cross-sectional illustration of a device 200 is shown, in accordance with an embodiment. As shown, the device 200 may comprise a substrate 210 and a patterning stack 235 may be provided over the substrate 210. In an embodiment, the substrate 210 may comprise any substrate used in semiconductor manufacturing. For example, the substrate 210 may comprise a semiconductor substrate, such as a silicon substate, a III-V semiconductor substrate, or the like. In an embodiment, the substrate 210 may also refer to a dielectric layer (e.g., silicon dioxide, silicon nitride, etc.), a metal layer, and/or the like that is provided over an underlying semiconductor layer.

In an embodiment, the patterning stack 235 may include any number of layers in order to implement a desired patterning result. For example, layers 231-234 are shown in FIG. 2A. The layers 231-234 may include materials that function as hardmask layers, antireflective coating layers, underlayers to improve the development process within the overlying photoresist layer, or the like. For example, the layer 231 may comprise an oxide material (e.g., silicon dioxide), the layer 232 may be a hardmask material, such one that comprises carbon, the layer 233 may comprise a silicon based layer (e.g., an amorphous silicon layer, a layer comprising silicon, oxygen, and nitrogen (e.g., SiON), or the like), and the layer 234 may comprise an antireflective coating, and underlayer, or the like. While one particular patterning stack 235 is shown in FIG. 2A, it is to be appreciated that the patterning stack may comprise one or more layers that are suitable for pattern transfer for a given patterning process.

In an embodiment, a patterned resist layer 220 is provided over the patterning stack 235. In an embodiment, the patterned resist layer 220 may comprise any suitable photoresist material that is compatible with a given lithography process. For example, the photoresist material may be compatible with a deep ultraviolet (DUV) lithography process, an EUV lithography process, or the like. In a particular embodiment, the patterned resist layer 220 may comprise a CAR or a MOR. Embodiments may also include a patterned resist layer 220 that comprises an organic molecular resist, an organometallic resist, or a self-immolative polymer resist. The photoresist material may be a positive tone resist or a negative tone resist.

In an embodiment, the patterned resist layer 220 may comprise a plurality of lines 225 that are spaced apart from each other. The lines 225 may be formed through a process that comprises a selective exposure to a particular wavelength of electromagnetic radiation (e.g., DUV or EUV), and the process may be followed by a development process in order to remove portions of the photoresist material between the plurality of lines 225.

In an embodiment, the plurality of lines 225 shown in FIG. 2A may extend into and out of the plane of FIG. 2A. In an embodiment, the plurality of lines 225 may be initially formed with a relatively high low frequency LER. For example, a magnitude of the curvature in the as deposited plurality of lines 225 may be approximately 2 nm or more, approximately 5 nm or more, or approximately 10 nm or more.

In order to reduce the low frequency LER, a capping layer 205 may be selectively applied over upper regions of the plurality of lines 225. In an embodiment, the capping layer 205 may induce a tensile stress into the plurality of lines 225. The tensile stress within the plurality of lines 225 may straighten the plurality of lines 225 in order to reduce the low frequency LER. For example, the resulting low frequency LER of the plurality of lines 225 after deposition of the capping layer 205 may be approximately 5 nm or less, or approximately 2 nm or less. While specific attention is provided herein to patterns within the resist layer that is patterned to form a plurality of lines 225, it is to be appreciated that capping layers 205 and processes described herein may be applicable to other types of patterns as well.

Referring now to FIG. 2B, a plan view illustration of the device 200 is shown, in accordance with an embodiment. The plan view of the device 200 illustrates the profile of the lines 225 (indicated with dashed lines) below the capping layer 205. As shown, the lines 225 with the capping layer 205 exhibit improved low frequency LER compared to the uncapped version of the plurality of lines 125 shown in FIG. 1B. That is, the lines 225 in FIG. 2B may exhibit reduced long-range undulation and a lower magnitude of the undulation. For example, the lines 225 in FIG. 2B may be substantially linear without significant low frequency LER.

In an embodiment, the capping layer 205 may comprise any suitable material that is able to induce the tensile stress into the underlying lines 225. For example, the capping layer 205 may comprise one or more of silicon (e.g., amorphous silicon), silicon nitride (e.g., SiN), or a carbon-based material (e.g., carbon). In some embodiments, the capping layer 205 may be free from metallic elements in order to prevent metallic contamination of other portions of the device 200 and/or contamination within the deposition and/or etching chambers.

In an embodiment, the capping layer 205 may be selectively deposited over the plurality of lines 225 so that the capping layer 205 is formed only over an upper region of the plurality of lines 225. For example, an angled deposition process may be used. Such a process will be described in greater detail below. As shown, the capping layer 205 may be deposited over a top surface of the plurality of lines 225 and along an upper sidewall portion 222 of the plurality of lines 225. That is, a lower sidewall portion 221 of the plurality of lines 225 may remain exposed after the deposition of the capping layer 205. Leaving the lower sidewall portion 221 of the plurality of lines 225 exposed allows for easier displacement of the plurality of lines 225 in response to the tensile stress. As such, the plurality of lines 225 may be straightened more easily.

In an embodiment, the upper sidewall portion 222 of the plurality of lines 225 may account for up to approximately 75% of a total sidewall height of each of the plurality of lines 225, up to approximately 50% of a total sidewall height of each of the plurality of lines 225, up to approximately 25% of a total sidewall height of each of the plurality of lines 225, up to approximately 10% of a total sidewall height of each of the plurality of lines 225, or up to approximately 5% of a total sidewall height of each of the plurality of lines 225.

In an embodiment, the deposition process may result in a thickness of the capping layer 205 along the upper sidewall portion 222 of the lines 225 being smaller than a thickness of the capping layer 205 over the top surface of the lines 225. In some embodiments, the thickness of the capping layer 205 along the upper sidewall portion 222 of the lines 225 may be non-uniform. For example, the thickness of the capping layer 205 along the upper sidewall portion 222 of the lines 225 may decrease as the distance from the top surface of the lines 225 increases. Additionally, the portion of the capping layer 205 over the top surface of the lines 225 may have a rounded or domed profile. More generally, a maximum width of the capping layer 205 over a line 225 may be wider than a maximum width of the line 225.

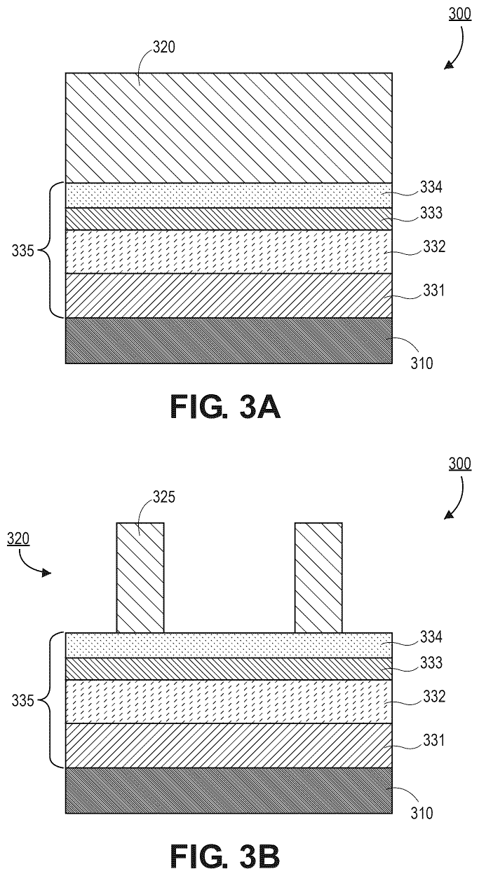

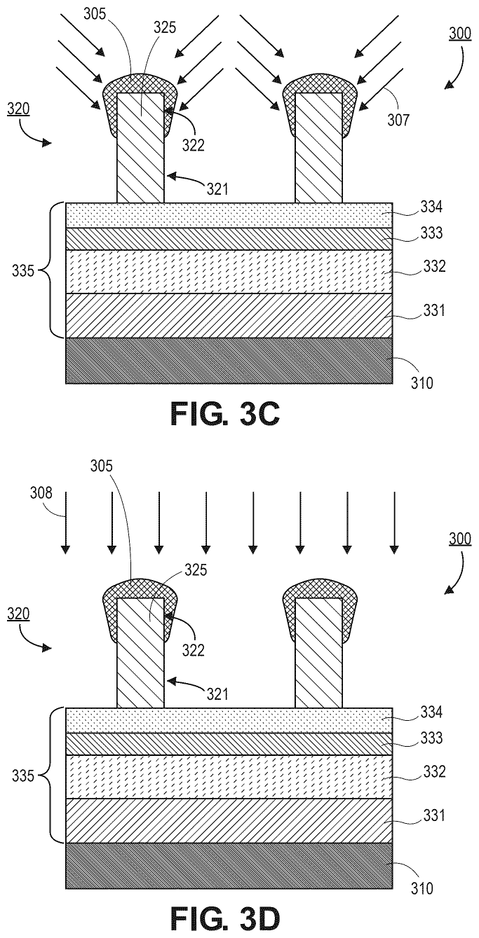

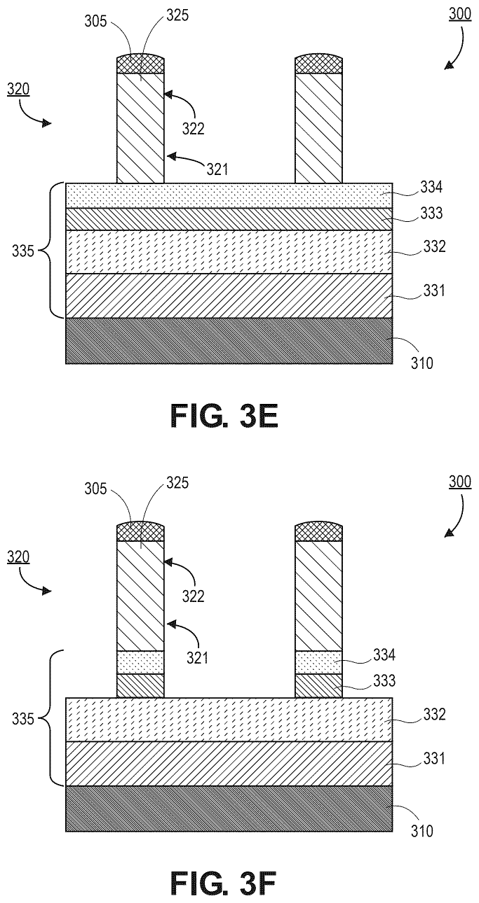

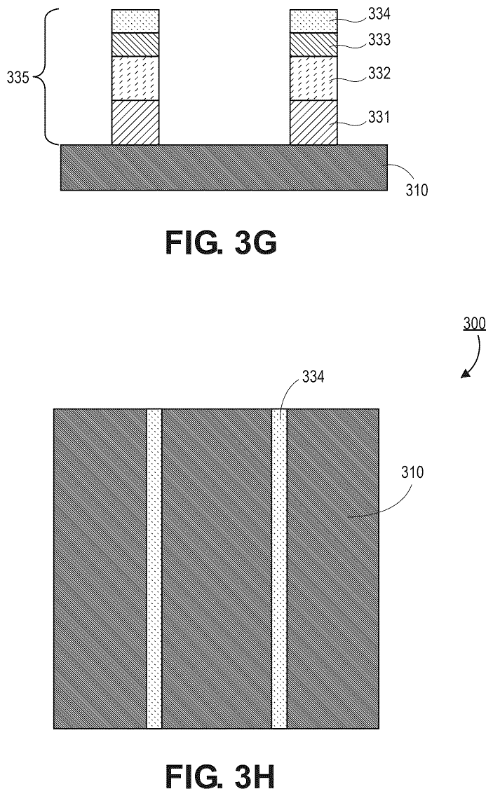

Referring now to FIGS. 3A-3H, a series of cross-sectional illustrations that depict a process for patterning a device 300 using a capping layer over lines 325 in a patterned resist layer 320 is shown, in accordance with an embodiment.

Referring now to FIG. 3A, a cross-sectional illustration of a portion of a device 300 is shown, in accordance with an embodiment. In an embodiment, the device 300 may include layers similar to those described above with respect to FIG. 2A. For example, the device 300 may comprise a substrate 310 with an overlying patterning stack 335. In an embodiment, the substrate 310 may comprise a semiconductor substrate, such as a silicon substate, a III-V semiconductor substrate, or the like. In an embodiment, the substrate 310 May also refer to a dielectric layer (e.g., silicon dioxide, silicon nitride, etc.), a metal layer, and/or the like that is provided over an underlying semiconductor layer.

In an embodiment, the patterning stack 335 may comprise one or more layers suitable for transferring a pattern into the device. For example, the patterning stack 335 in FIG. 3A depicts a stack of four layers 331, 332, 333, and 334. The layers 331-334 may be similar to the layers 231-234 described in greater detail herein.

In an embodiment, a resist layer 320 may be provided over the patterning stack 335. The resist layer 320 may comprise a resist material that is compatible with DUV lithography, EUV lithography, or the like. In an embodiment, the resist layer 320 may comprise a MOR material, a CAR material, or the like. The resist layer 320 may be a positive tone resist or a negative tone resist. In an embodiment, the resist layer 320 may be applied over the patterning stack 335 with a dry deposition process (e.g., CVD, atomic layer deposition (ALD), etc.) or through a wet deposition process (e.g., a spin coating process).

Referring now to FIG. 3B, a cross-sectional illustration of the portion of the device 300 after the resist layer 320 is patterned to form a plurality of lines 325 is shown, in accordance with an embodiment. In an embodiment, the resist layer 320 may be patterned with any suitable lithography process. For example, the resist layer 320 may be selectively exposed to electromagnetic radiation (e.g., DUV radiation or EUV radiation) through a mask, a reticle, or the like. The exposed regions may undergo a chemical change in order to produce a solubility switch in the exposed regions of the resist layer 320. A bake or other heating process may also be applied after exposure. Thereafter, a developing process (e.g., a wet etch) may be used in order to remove portions of the resist layer 320 in order to leave behind a desired pattern. For example, the pattern shown in FIG. 3B includes a plurality lines 325.

In an embodiment, the plurality of lines 325 may have undesirable low frequency LER at this point. For example, the lines 325 may have a profile similar to the profile of the lines 125 shown in FIG. 1B. Since low frequency LER is typically not curable through subsequent processing operations (e.g., plasma etching), embodiments disclosed herein include adding a capping layer 305 to the plurality of lines 325. The capping layer 305 applies a tensile stress to the lines 325 in order to straighten the lines and reduce the low frequency LER.

Referring now to FIG. 3C, a cross-sectional illustration of the portion of the device 300 after the capping layer 305 is deposited on each of the plurality of lines 325 is shown, in accordance with an embodiment. In an embodiment, the capping layer 305 may comprise any suitable material that is able to induce the tensile stress into the underlying lines 325. For example, the capping layer 305 may comprise one or more of silicon (e.g., amorphous silicon), silicon nitride (e.g., SiN), or a carbon-based material (e.g., carbon). In some embodiments, the capping layer 305 may be free from metallic elements in order to prevent metallic contamination of other portions of the device 300 and/or contamination within the deposition and/or etching chambers.

In an embodiment, the capping layer 305 may be selectively deposited over the plurality of lines 325 so that the capping layer 305 is formed only over an upper region of the plurality of lines 325. For example, an angled deposition process (as indicated by angled lines 307) may be used. In an embodiment, the angled deposition process may comprise an angled CVD process, an angled PVD process, an angled ALD process, or the like. In an embodiment, the angle used for the deposition process may be at least partially dependent on an aspect ratio of the lines 325 and/or a spacing between neighboring lines. For example, higher aspect ratios (height:width) for the lines 325 and smaller spacings may benefit from the use smaller angles (with respect to a normal of the surface of the device). In some embodiments, the angle used may be between approximately 30° and approximately 60°.

As shown, the angled deposition allows for the capping layer 305 to be deposited over a top surface of the plurality of lines 325 and along an upper sidewall portion 322 of the plurality of lines 325. That is, a lower sidewall portion 321 of the plurality of lines 325 may remain exposed after the deposition of the capping layer 305. Leaving the lower sidewall portion 321 of the plurality of lines 325 exposed allows for easier displacement of the plurality of lines 325 in response to the tensile stress. As such, the plurality of lines 325 may be straightened more easily.

Referring now to FIG. 3D, a cross-sectional illustration of the portion of the device 300 after a treatment is applied to the device is shown, in accordance with an embodiment. In an embodiment, the treatment (as indicated by lines 308) may include one or more of a UV treatment, a thermal annealing treatment, and/or an oxidation treatment. Such treatments may be applied to the device 300 before and/or after the deposition of the capping layer 305. In other embodiments, the treatment may also be provided during the deposition of the capping layer 305. For example, the deposition of the capping layer 305 at an elevated temperature may bring the resist layer 320 to a temperature around the glass transition temperature of the resist layer 320. This may allow for the resist layer 320 to be deformed as the tensile stressing material of the capping layer 305 is deposited. In some instances, the treatments may modify the atomic arrangement of the patterned lines 325 and/or the capping layer 305 in order to generate tensile stress in the material through changes in the lattice structure of elements within the materials.

Referring now to FIG. 3E, a cross-sectional illustration of the device 300 after a trimming process is shown, in accordance with an embodiment. In an embodiment, the trimming process may include removing portions of the capping layer 305 that cover the upper sidewall portions 322 of the plurality of lines 325. Removing the capping layer 305 from the upper sidewall portions 322 of the plurality of lines 325 may allow for better pattern transfer in some embodiments. For example, the trimmed capping layer 305 will not shadow portions of the patterning stack 335 between the plurality of lines 325. As such, the pattern of the lines 325 may be more accurately transferred into the underlying patterning stack 335. In an embodiment, the trimming process may be implemented with a directional dry etching process or the like. In some embodiments, the remaining portion of the capping layer 305 induces sufficient stress into the lines 325 so that they maintain an optimal low frequency LER.

Referring now to FIG. 3F, a cross-sectional illustration of the portion of the device 300 after the pattern of the resist layer 320 is transferred into at least a portion of the patterning stack 335 is shown, in accordance with an embodiment. That is, the lines 325 may be used as a mask in order to transfer the pattern into one or more layers of the patterning stack 335. For example, the layers 334 and 333 may be patterned with an etching process, such as a dry etching process.

Referring now to FIG. 3G, a cross-sectional illustration of the portion of the device 300 after the pattern is transferred through a remainder of the patterning stack 335 is shown, in accordance with an embodiment. In some embodiments, the resist layer 320 and the capping layer 305 may be removed with any suitable process. An additional etching process (e.g., a dry etching process) may be used to continue the pattern through the layers 332 and 331 in order to expose portions of the underlying substrate 310. In some embodiments, the underlying substrate 310 may also be etched while using the remaining portions of the patterning stack 335 as a mask layer.

Referring now to FIG. 3F, a plan view illustration of the portion of the device 300 after the patterning stack 335 is patterned is shown, in accordance with an embodiment. As shown, the resulting pattern of the patterning stack 335 has optimal low frequency LER as indicated by the straight edges of the layer 334. This allows for optimal pattern transfer into the substrate 310 while maintaining good low frequency LER.

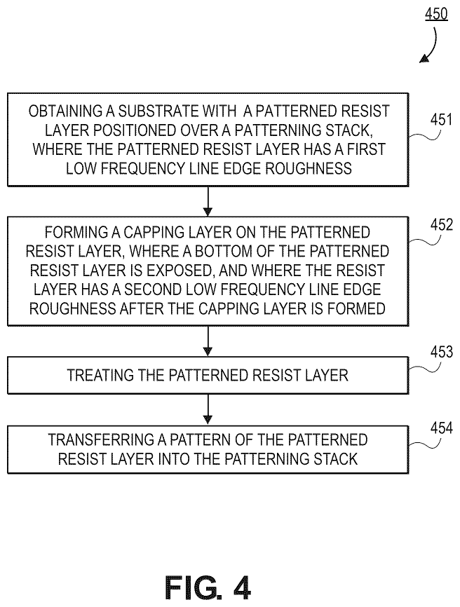

Referring now to FIG. 4, a flow diagram depicting a process 450 for patterning a device with a patterning process that includes forming a selective capping layer over the pattern in the resist layer is shown, in accordance with an embodiment. In an embodiment, the process 450 may be similar to processes described with respect to FIGS. 3A-3F.

In an embodiment, the process 450 may begin with operation 451, which comprises obtaining a substrate with a patterned resist layer positioned over a patterning stack. In an embodiment, the patterned resist layer comprises a first low frequency line edge roughness. In an embodiment, the resist layer may comprise a MOR or a CAR. The resist layer may have a positive tone resist or a negative tone resist. In an embodiment, the resist layer is patterned with a DUV lithography process or an EUV lithography process. In some embodiments, the pattern may include a plurality of lines. In some embodiments, obtaining the substrate may comprise receiving a substrate with an unpatterned resist layer and subsequently patterning the resist layer. The pattern may be developed after the substrate is obtained (i.e., the resist layer may already be exposed). In other embodiments, the resist layer may be exposed and developed after the substrate is obtained. In some embodiments, obtaining the substrate may comprise receiving a substrate that has a fully patterned (i.e., exposed and developed) resist layer.

In an embodiment, the process 450 may continue with operation 452, which comprises forming a capping layer on the patterned resist layer. In an embodiment, a bottom of the patterned resist layer remains exposed. In an embodiment the patterned resist layer may have a second low frequency line edge roughness that is lower than the first low frequency line edge roughness after the capping layer is formed. In an embodiment, the capping layer is applied with an angled CVD process or an angled PVD process. For example, the angle may be between approximately 30° and approximately 60°. In an embodiment, the capping layer comprises one or more of silicon, carbon, or nitrogen. For example, the capping layer may comprise amorphous Si, SiN, or C. In some embodiments, the capping layer may be formed in the same tool used to develop the pattern of the resist layer. In other embodiments, the pattern may be developed in a first tool, and the capping layer may be applied in a second tool.

In an embodiment, the process 450 may continue with operation 453, which comprises treating the patterned resist layer. In an embodiment, the treatment may be applied before and/or after the capping layer is formed. In an embodiment, the treatment may include one or more of a UV treatment, a thermal annealing treatment, or an oxidation treatment.

In some embodiments, the capping layer may be trimmed after it has been deposited onto the patterned resist layer. For example, the trimming process may include a directional etching process that results in the capping layer having a first width that substantially matches a second width of an individual line of the patterned resist layer.

In an embodiment, the process 450 may continue with operation 454, which comprises transferring a pattern of the patterned resist layer into the patterning stack. For example, the pattern may comprise a plurality of lines. The pattern may be transferred into the patterning stack with one or more etching process (e.g., dry etching processes).

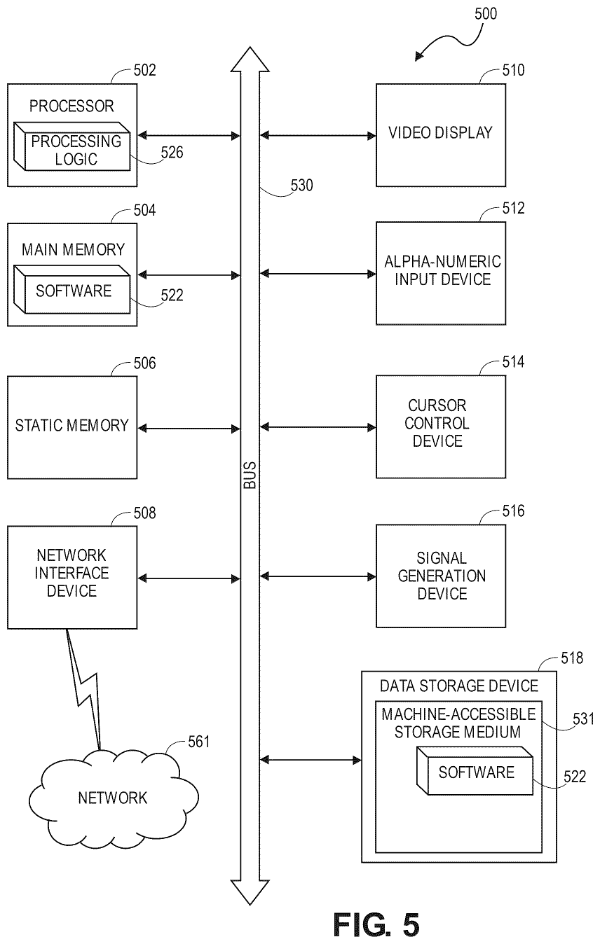

Referring now to FIG. 5, a block diagram of an exemplary computer system 500 of a processing tool is illustrated in accordance with an embodiment. In an embodiment, computer system 500 is coupled to and controls processing in the processing tool. Computer system 500 may be connected (e.g., networked) to other machines in a Local Area Network (LAN), an intranet, an extranet, or the Internet. Computer system 500 may operate in the capacity of a server or a client machine in a client-server network environment, or as a peer machine in a peer-to-peer (or distributed) network environment. Computer system 500 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 500, the term “machine” shall also be taken to include any collection of machines (e.g., computers) that individually or jointly execute a set (or multiple sets) of instructions to perform any one or more of the methodologies described herein.

Computer system 500 may include a computer program product, or software 522, having a non-transitory machine-readable medium having stored thereon instructions, which may be used to program computer system 500 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 500 includes a system processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

System processor 502 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 502 may also be one or more special-purpose processing devices such as an application specific integrated circuit (ASIC), a field programmable gate array (FPGA), a digital signal system processor (DSP), network system processor, or the like. System processor 502 is configured to execute the processing logic 526 for performing the operations described herein.

The computer system 500 may further include a system network interface device 508 for communicating with other devices or machines. The computer system 500 may also include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium 531 (or more specifically a computer-readable storage medium) on which is stored one or more sets of instructions (e.g., software 522) embodying any one or more of the methodologies or functions described herein. The software 522 may also reside, completely or at least partially, within the main memory 504 and/or within the system processor 502 during execution thereof by the computer system 500, the main memory 504 and the system processor 502 also constituting machine-readable storage media. The software 522 may further be transmitted or received over a network 561 via the system network interface device 508. In an embodiment, the network interface device 508 may operate using RF coupling, optical coupling, acoustic coupling, or inductive coupling.

While the machine-accessible storage medium 531 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
obtaining a substrate with a patterned resist layer positioned over a patterning stack, wherein the patterned resist layer comprises a first low frequency roughness; and
forming a capping layer on the patterned resist layer, wherein a bottom of the patterned resist layer is exposed, and wherein the patterned resist layer has a second low frequency line edge roughness that is lower than the first low frequency line edge roughness after the capping layer is formed.

2. The method of claim 1, wherein the patterned resist layer comprises a metal oxide resist material or a chemically amplified resist.

3. The method of claim 1, wherein the patterned resist layer comprises an organic molecular resist, an organometallic resist, or a self-immolative polymer resist.

4. The method of claim 1, wherein the capping layer is applied with an angled chemical vapor deposition process or an angled physical vapor deposition process.

5. The method of claim 4, wherein an angle of the angled chemical vapor deposition process or the angled physical vapor deposition process is between approximately 30° and approximately 60°.

6. The method of claim 1, wherein the capping layer comprises one or more of silicon, carbon, or nitrogen.

7. The method of claim 1, further comprising:
trimming the capping layer so that the capping layer has a first width that substantially matches a second width of an individual line of the patterned resist layer.

8. The method of claim 1, further comprising:
applying a treatment to the patterned resist layer before the capping layer is formed, after the capping layer is formed, or during the formation of the capping layer.

9. The method of claim 8, wherein the treatment comprises one or more of an ultraviolet treatment, a thermal annealing treatment, or an oxidation treatment.

10. The method of claim 1, wherein the patterned resist layer is formed through an extreme ultraviolet exposure and development process.

11. A method, comprising:
obtaining a substrate with a patterned resist layer positioned over a patterning stack, wherein the patterned resist layer comprises a line, and wherein the line has a curvature with a first magnitude;
forming a capping layer over the line, wherein the capping layer covers a portion of a sidewall of the line, and wherein the capping layer induces a tensile stress into the line to change the curvature so that the curvature has a second magnitude that is smaller than the first magnitude.

12. The method of claim 11, further comprising:
trimming the capping layer so that an entire sidewall of the line is exposed.

13. The method of claim 11, wherein the capping layer is applied with an angled chemical vapor deposition process or an angled physical vapor deposition process.

14. The method of claim 11, wherein the capping layer comprises one or more of silicon, carbon, or nitrogen.

15. The method of claim 11, further comprising:
applying a treatment to the patterned resist layer before the capping layer is formed, after the capping layer is formed, or during the formation of the capping layer.

16. The method of claim 15, wherein the treatment comprises one or more of an ultraviolet treatment, a thermal annealing treatment, or an oxidation treatment.

17. The method of claim 11, wherein the patterned resist layer comprises a chemically amplified resist layer or a metal oxide resist layer.

18. A method, comprising:
obtaining a substrate with a patterned resist layer with a plurality of lines positioned over a patterning stack, wherein the patterned resist layer comprises a chemically amplified resist layer or a metal oxide resist layer;
forming a capping layer over the plurality of lines, wherein the capping layer covers upper portions of the plurality of lines, and wherein bottom portions of the plurality of lines are exposed; and
transferring a pattern of the patterned resist layer into the patterning stack.

19. The method of claim 18, wherein the capping layer comprises one or more of silicon, carbon, or nitrogen.

20. The method of claim 18, further comprising:
applying a treatment to the patterned resist layer before the capping layer is formed, after the capping layer is formed, or during the formation of the capping layer, wherein the treatment comprises one or more of an ultraviolet treatment, a thermal annealing treatment, or an oxidation treatment.
